(19) United States
(12) Patent Application Publication
(10) Pub. No.: US 2016/0225744 A1
(43) Pub. Date: Aug. 4, 2016

(54) SEMICONDUCTOR PACKAGES, METHODS OF FABRICATING THE SAME, MEMORY CARDS INCLUDING THE SAME AND ELECTRONIC SYSTEMS INCLUDING THE SAME

(71) Applicant: SK Hynix Inc., Icheon (KR)

(72) Inventors: Jong Hyun NAM, Seoul (KR); Pil Soon BAE, Icheon (KR)

(21) Appl. No.: 14/748,037

(22) Filed: Jun. 23, 2015

(30) Foreign Application Priority Data
Jan. 29, 2015 (KR) 10-2015-0014001

(51) Int. Cl. H01L 25/065; H01L 23/31; H01L 23/00; H01L 23/498

(52) U.S. Cl. CPC H01L 25/0657; H01L 23/49838; H01L 23/3121; H01L 24/48; H01L 23/3142; H01L 23/49827; H01L 2225/0651; H01L 2225/06548; H01L 2225/06572; H01L 2224/48227; H01L 2224/48235; H01L 2924/15153

(57) ABSTRACT

A semiconductor package includes a package substrate having a cavity therein and a second internal contact portion, a semiconductor die disposed in the cavity of the package substrate and having a first internal contact portion, a bonding wire connecting the first internal contact portion to the second internal contact portion, and an encapsulation part covering surfaces of the semiconductor die and the package substrate and providing an opening that exposes a first external contact portion of the bonding wire. Related memory cards and related electronic systems are also provided.

### CROSS-REFERENCE TO RELATED APPLICATION

The present application claims priority under 35 U.S.C 119(a) to Korean Application No. 10-2015-0014001, filed on Jan. 29, 2015, in the Korean intellectual property Office, which is incorporated herein by reference in its entirety as set forth in full.

### BACKGROUND

1. Technical Field

Embodiments of the present disclosure relate to package technologies, and more particularly, to semiconductor packages, methods of fabricating the same, memory cards including the same and electronic systems including the same.

2. Related Art

Semiconductor packages which are capable of processing a large amount of data are increasingly in demand with the development of smaller electronic systems such as mobile systems. As the electronic systems become lighter and smaller, the semiconductor packages employed in the electronic systems have been continuously scaled down. In addition, a large capacity of semiconductor packages are increasingly in demand with the development of multi-functional electronic systems. Many efforts to put a plurality of semiconductor chips in a single package have been attempted to provide a large capacity of semiconductor packages such as stack packages. In such cases, it may be necessary to reduce a thickness of the semiconductor chips to realize thin stack packages.

### SUMMARY

Various embodiments are directed to semiconductor packages, methods of fabricating the same, memory cards including the same and electronic systems including the same.

According to an embodiment, a semiconductor package includes a package substrate having a cavity therein and a second internal contact portion, a semiconductor die disposed in the cavity of the package substrate and provided to have a first internal contact portion, a bonding wire connecting the first internal contact portion to the second internal contact portion, and an encapsulation part covering the semiconductor die and the package substrate and providing an opening that exposes a portion of the bonding wire. The exposed portion of the bonding wire acts as a first external contact portion.

According to another embodiment, a semiconductor package includes a first sub-package and a second sub-package stacked on the first sub-package. The first sub-package includes a first package substrate having a first cavity therein and a first outer internal contact portion, a first semiconductor die disposed in the first cavity and provided to have a first inner internal contact portion, a first bonding wire connecting the first inner internal contact portion to the first outer internal contact portion, and a first encapsulation part covering the first semiconductor die and the first package substrate and providing a first opening that exposes a portion of the first bonding wire. The exposed portion of the first bonding wire acts as a first upper external contact portion. The second sub-package includes a second connection member which is connected to the first upper external contact portion of the first sub-package.

According to another embodiment, there is provided a method of fabricating a semiconductor package. The method includes providing a package substrate portion having cavities therein and second internal contact portions, disposing semiconductor dies including first internal contact portions in respective ones of the cavities of the package substrate portion, forming bonding wires that electrically connect the second internal contact portions to the first internal contact portions, and forming an encapsulation part on the semiconductor dies and the package substrate portion. The encapsulation part provides opening portions that expose portions of the bonding wires. The encapsulation part and the package substrate portion are cut to provide a plurality of separate semiconductor packages. The exposed portions of the bonding wires act as first external contact portions.

According to another embodiment, there is provided a memory card including a package. The package includes a package substrate having a cavity therein and a second internal contact portion, a semiconductor die disposed in the cavity of the package substrate and provided to have a first internal contact portion, a bonding wire connecting the first internal contact portion to the second internal contact portion, and an encapsulation part covering the semiconductor die and the package substrate and providing an opening that exposes a portion of the bonding wire. The exposed portion of the bonding wire acts as a first external contact portion.

According to another embodiment, there is provided a memory card including a package. The package includes a first sub-package and a second sub-package stacked on the first sub-package. The first sub-package includes a first package substrate having a first cavity therein and a first outer internal contact portion, a first semiconductor die disposed in the first cavity and provided to have a first inner internal contact portion, a first bonding wire connecting the first inner internal contact portion to the first outer internal contact portion, and a first encapsulation part covering the first semiconductor die and the first package substrate and providing a first opening that exposes a portion of the first bonding wire. The exposed portion of the first bonding wire acts as a first upper external contact portion. The second sub-package includes a second connection member which is connected to the first upper external contact portion of the first sub-package.

According to another embodiment, there is provided an electronic system including a package. The package includes a package substrate having a cavity therein and a second internal contact portion, a semiconductor die disposed in the cavity of the package substrate and provided to have a first internal contact portion, a bonding wire connecting the first internal contact portion to the second internal contact portion, and an encapsulation part covering the semiconductor die and the package substrate and providing an opening that exposes a portion of the bonding wire. The exposed portion of the bonding wire acts as a first external contact portion.

According to another embodiment, there is provided an electronic system including a package. The package includes a first sub-package and a second sub-package stacked on the first sub-package. The first sub-package includes a first package substrate having a first cavity therein and a first outer internal contact portion, a first semiconductor die disposed in the first cavity and provided to have a first inner internal contact portion, a first bonding wire connecting the first inner internal contact portion to the first outer internal contact portion, and a first encapsulation part covering the first semiconductor die and the first package substrate and providing a first opening that exposes a portion of the first bonding wire. The exposed portion of the first bonding wire acts as a first upper external contact portion. The second sub-package includes a second connection member which is connected to the first upper external contact portion of the first sub-package.

### BRIEF DESCRIPTION OF THE DRAWINGS

Various embodiments of the present disclosure will become more apparent in view of the attached drawings and accompanying detailed description, in which:

FIG. 1 is a cross-sectional view illustrating a semiconductor package according to an embodiment;

FIG. 2 is a perspective view illustrating a package substrate of a semiconductor package according to an embodiment;

FIG. 3 is a plan view illustrating a connection structure between a semiconductor die and a package substrate included in a semiconductor package according to an embodiment;

FIGS. 4 to 7 are cross-sectional views illustrating bonding wires of a semiconductor package according to an embodiment;

FIG. 8 is a perspective view illustrating a semiconductor package according to an embodiment;

FIG. 9 is a cross-sectional view illustrating a semiconductor package according to another embodiment;

FIG. 10 is a cross-sectional view illustrating a semiconductor package according to still another embodiment;

FIG. 11 is a cross-sectional view illustrating a semiconductor package according to yet another embodiment;

FIGS. 12 to 17 are cross-sectional views illustrating a method of fabricating a semiconductor package according to an embodiment;

FIG. 18 is a block diagram illustrating an electronic system employing a memory card including a package according to an embodiment; and

FIG. 19 is a block diagram illustrating an electronic system including a package according to an embodiment.

### DETAILED DESCRIPTION OF THE EMBODIMENTS

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concept.

It will also be understood that when an element is referred to as being “on,” “above,” “below,” or “under” another element, it can be directly “on,” “above,” “below,” or “under” the other element, respectively, or intervening elements may also be present. Accordingly, the terms such as “on,” “above,” “below,” or “under” which are used herein are for the purpose of describing particular embodiments only and are not intended to limit the inventive concept.

It will be further understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion.

In the following embodiments, the elements referred to as semiconductor chips may be obtained by separating a semiconductor substrate such as a wafer on which electronic circuits are integrated into a plurality of dies using a die sawing process. In some cases, each of the semiconductor chips may include a semiconductor die mounted on a package substrate or a plurality of semiconductor dies stacked on a package substrate. If a plurality of semiconductor dies are stacked on a package substrate to form a semiconductor package, the plurality of semiconductor dies may be electrically connected to each other by through electrodes (or through vias) such as through silicon vias (TSVs). The semiconductor chips may correspond to memory chips. The memory chips may include dynamic random access memory (DRAM) circuits, static random access memory (SRAM) circuits, flash circuits, magnetic random access memory (MRAM) circuits, resistive random access memory (ReRAM) circuits, ferroelectric random access memory (FeRAM) circuits or phase change random access memory (PcRAM) circuits which are integrated on and/or in the semiconductor substrate. Alternatively, the semiconductor chips may correspond to logic chips including logic circuits which are integrated on and/or in the semiconductor substrate.

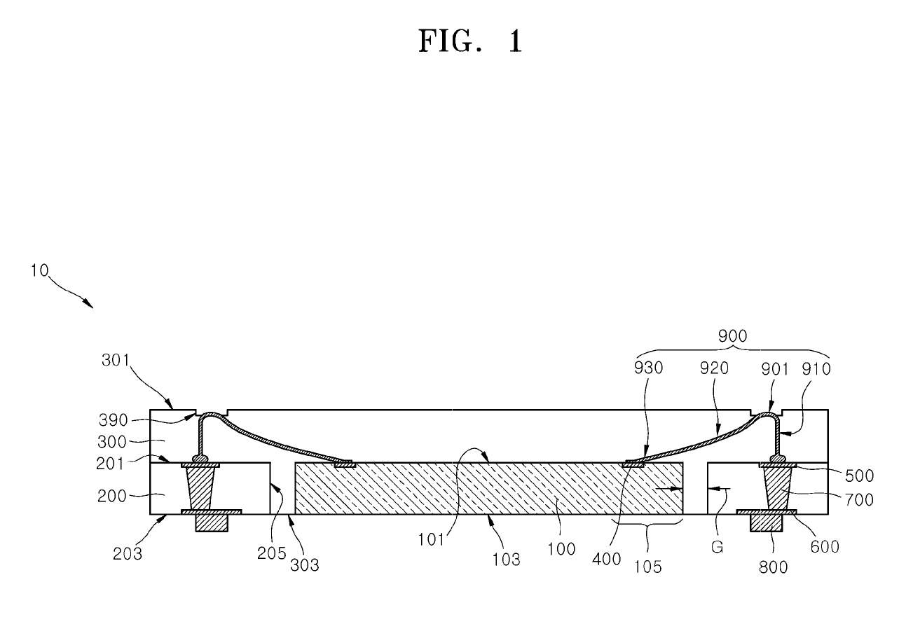

FIG. 1 is a cross-sectional view illustrating a semiconductor package 10 according to an embodiment.

Referring to FIG. 1, the semiconductor package 10 may include a semiconductor die 100, a package substrate 200, an encapsulation part 300 and bonding wires 900. The package substrate 200 may surround sidewalls of the semiconductor die 100, and the encapsulation part 300 may cover a surface of the semiconductor die 100 and a surface of the package substrate 200. The bonding wires 900 may electrically connect the semiconductor die 100 to the package substrate 200. The semiconductor die 100 may have a first surface 101 and include first internal contact portions 400 disposed at the first surface 101. Each of the first internal contact portions 400 may be provided in a pad form, and connection members may be bonded to the first internal contact portions 400. The first internal contact portions 400 may be disposed at the first surface 101 in edge portions 105 of the semiconductor die 100.

The semiconductor die 100 may also have a second surface 103 on the opposite side of the die from the first surface 101. The second surface 103 of the semiconductor die 100 may not be covered with the encapsulation part 300 or the package substrate 200 but may be exposed to an external environment. The encapsulation part 300 may include a molding material such as an epoxy molding compound (EMC) material or a dielectric material.

The encapsulation part 300 may be formed by a molding process to have a predetermined shape. The encapsulation part 300 may fill a gap region G between the semiconductor die 100 and the package substrate 200. The encapsulation part 300 may cover the second surface 103 of the semiconductor die 100. However, in some embodiments, the encapsulation part 300 may be molded so that the second surface 103 of the semiconductor die 100 is exposed to reduce a thickness of the semiconductor package 10.

The bonding wires 900 may be encapsulated by the encapsulation part 300. In such a case, a first external contact portion 901 of each bonding wire 900 may be exposed by a hole in the encapsulation part 300.

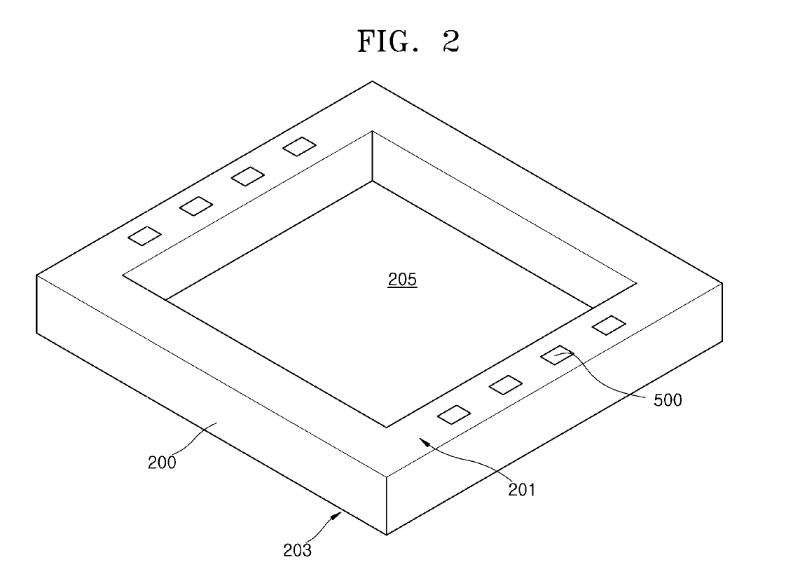

FIG. 2 is a perspective view illustrating the package substrate 200 of the semiconductor package 10 shown in FIG. 1.

Referring to FIGS. 1 and 2, the package substrate 200 may include a dielectric layer or an insulation layer. The package substrate 200 may be, for example, a printed circuit board (PCB). The package substrate 200 may have a cavity 205. The cavity 205 may include a space in which the semiconductor die 100 is inserted. The cavity 205 may have a polygon shape which can be formed by removing a portion of the package substrate 200. The cavity 205 may penetrate a portion of the package substrate 200. In such a case, the package substrate 200 may have a rectangular frame shape, and the cavity 205 may penetrate a central portion of the package substrate 200 to have a tetragonal shape (e.g., a rectangular shape) in a plan view.

The package substrate 200 may have a third surface 201, and second internal contact portions 500 may be disposed at the third surface 201 of the package substrate 200. Each of the second internal contact portions 500 may have a landing pad form and may be electrically connected to one of the first internal contact portions 400. The second internal contact portions 500 may be conductive patterns which are formed on a body portion of the package substrate 200 by a PCB fabrication process. The second internal contact portions 500 may include a metal material such as aluminum (Al), copper (Cu), nickel (Ni) or gold (Au), which is used in fabrication of the PCB.

The package substrate 200 may also have a fourth surface 203 on the opposite of the substrate from the third surface 201. Second external contact portions 600 may be disposed at the fourth surface 203 of the package substrate 200. The package substrate 200 may include internal connectors 700 that electrically connect the second internal contact portions 500 to the second external contact portions 600. The internal connectors 700 may correspond to through vias that substantially penetrate the body portion of the package substrate 200.

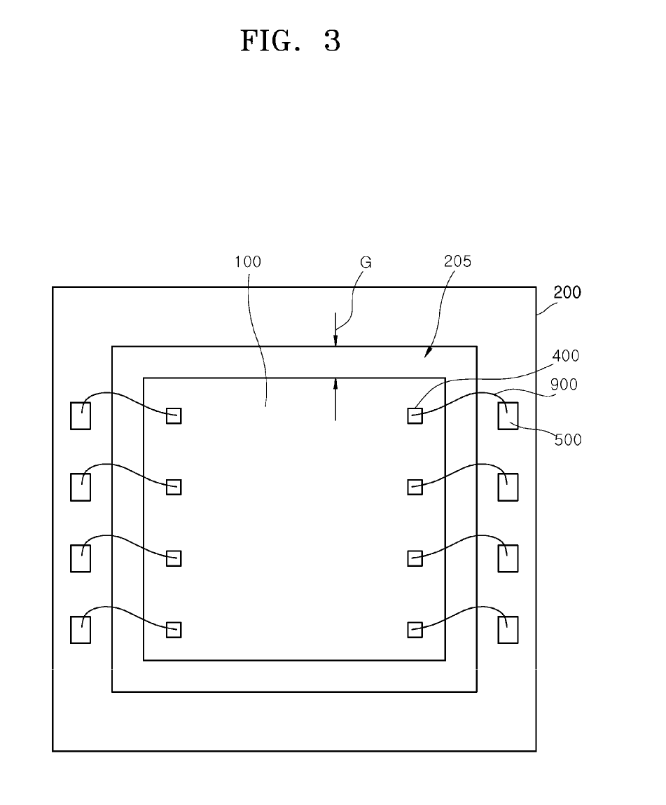

FIG. 3 is a plan view illustrating a connection structure between the semiconductor die 100 and the package substrate 200 of the semiconductor package 10 shown in FIG. 1.

Referring to FIGS. 1 and 3, the semiconductor package 10 may include the bonding wires 900 that electrically connect the first internal contact portions 400 of the semiconductor die 100 to the second internal contact portions 500 of the package substrate 200. The semiconductor die 100 may be disposed in the cavity 205 of the package substrate 200, and the gap region G may exist between the semiconductor die 100 and the package substrate 200. The semiconductor die 100 may be electrically connected to the package substrate 200 by the bonding wires 900.

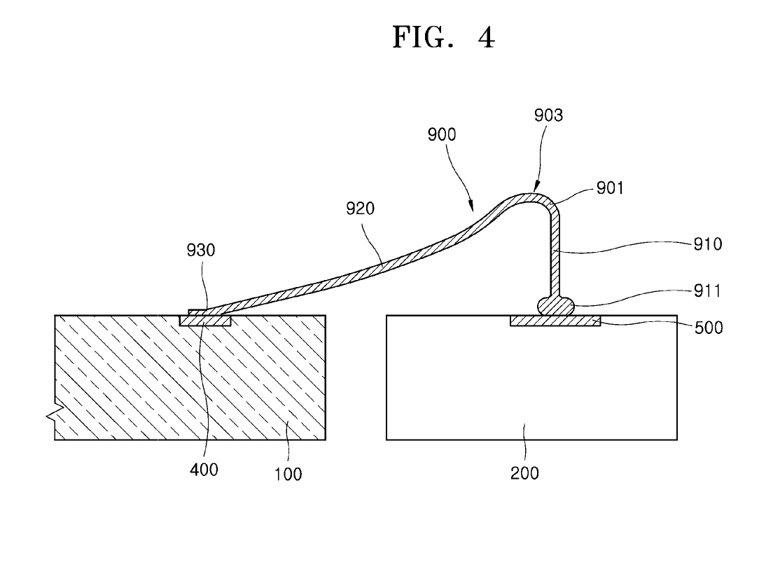

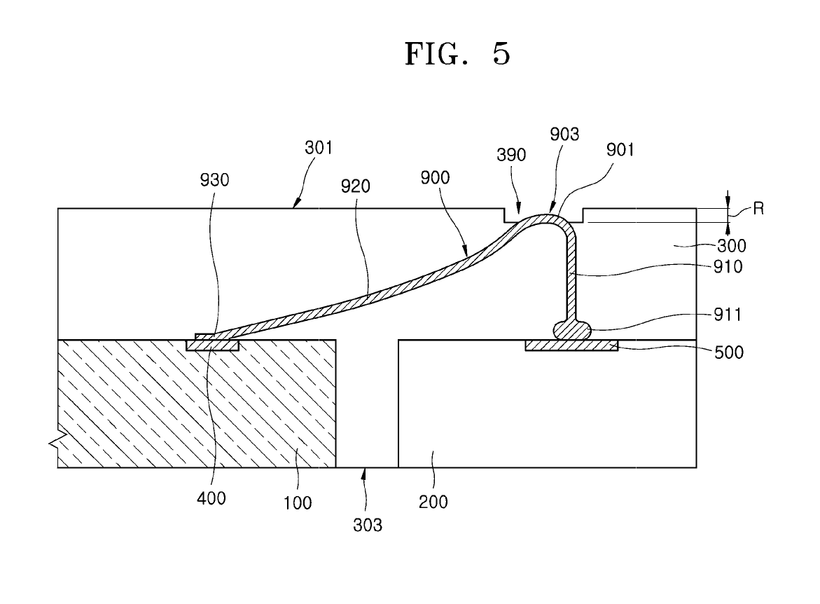

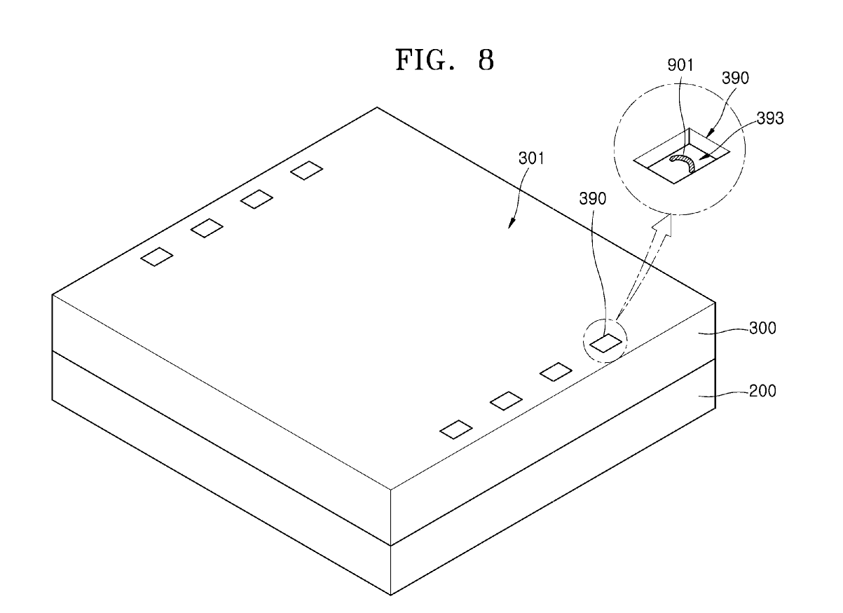

FIGS. 4 to 7 are cross-sectional views illustrating the bonding wires 900 of the semiconductor package 10 shown in FIG. 1, and FIG. 8 is a perspective view illustrating the semiconductor package 10 shown in FIG. 1.

Referring FIGS. 1 and 4, the semiconductor package 10 may include the bonding wires 900 that electrically connect the semiconductor die 100 to the package substrate 200. Each of the bonding wires 900 may have a filament shape including a substrate connection portion 911, a first extension portion 910 extending from the substrate connection portion 911, the first external contact portion 901, a second extension portion 920 and a die connection portion 930 which are connected in series. The bonding wires 900 may be metal wires such as gold wires formed by a wire bonding process.

As illustrated in FIG. 4, when each of the bonding wires 900 are bonded to the package substrate 200, each substrate connection portion 911 having a ball shape may connect to one of the second internal contact portions 500 of the package substrate 200. In addition, the first extension portion 910 may extend from the substrate connection portion 911 at a substantially right angle to a surface of the second internal contact portion 500. An upper bend portion 903 may extend from the first extension portion 910 and bend toward one of the first internal contact portions 400 at an apex of the bonding wire 900. Part of the upper bend portion 903 may be exposed by an opening in the encapsulation part 300, and the exposed part may be referred to as the first external contact portion 901. The second extension portion 920 may extend from the upper bend 901 to the first internal contact portion 400. The die connection portion 930 may be an end of the second extension portion 920 and may directly contact the first internal contact portion 400. That is, the die connection portion 930 may be mechanically bonded to the first internal contact portion 400. The first external contact portion 901 of the bonding wire 900 may overlap with the second internal contact portion 500 or may be adjacent to the second internal contact portion 500, when viewed from a plan view.

Referring to FIGS. 1, 4 and 5, the semiconductor package 10 may include the encapsulation part 300 that buries the bonding wires 900 therein and covers the first surface 101 of the semiconductor die 100 and the third surface 201 of the package substrate 200. The encapsulation part 300 may have a fifth surface 301 which is located at an opposite side to the semiconductor die 100. A portion of the fifth surface 301 may be recessed as an opening 390 corresponding to a window where the first external contact portion 901 is exposed. The exposed first external contact portion 901 may be electrically connected to an external system or another semiconductor die.

The fifth surface 301 of the encapsulation part 300 may correspond to a top surface of the semiconductor package 10. Thus, the exposed first external contact portions 901 may be adjacent to the top surface of the semiconductor package 10. The encapsulation part 300 may also have a sixth surface 303 on an opposite side from the fifth surface 301, and the second external contact portions 600 may be disposed at the fourth surface 203 of the package substrate 200 adjacent to the sixth surface 303 of the encapsulation part 300. As a result, the first external contact portions 901 and the second external contact portions 600 may be disposed at a top surface (i.e., the fifth surface 301) and a bottom surface (i.e., the fourth surface 203) of the semiconductor package 10, respectively. Thus, the semiconductor package 10 may be electrically connected to an external system or another semiconductor package through the first external contact portions 901 or the second external contact portions 600.

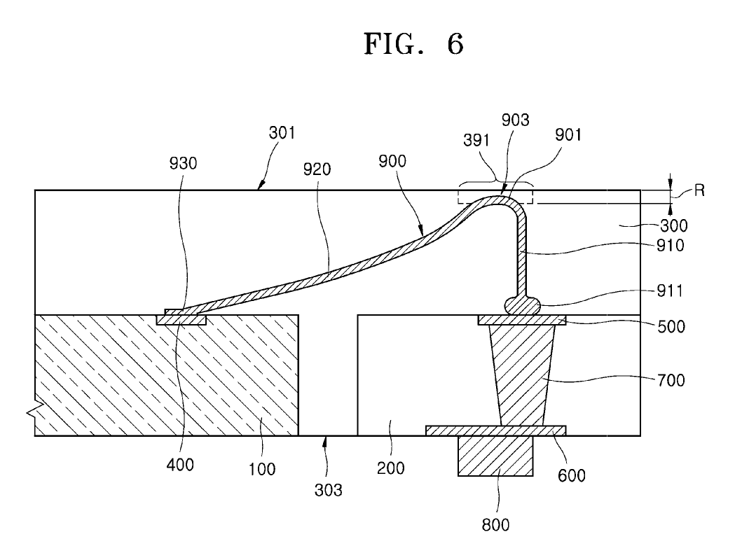

Referring to FIGS. 1, 5, 6, 7 and 8, the semiconductor package 10 may include the encapsulation part 300 that includes the openings 390 which holes with bottom surfaces 393 at which the first external contact portions 901 of the bonding wires 900 are exposed. As illustrated in FIG. 6, each of the first external contact portions 901 of the bonding wires 900 is disposed at an upper bend 903 of a bonding wire 900. Thus, the first external contact portions 901 of the bonding wires 900 may be adjacent to the fifth surface 301 of the encapsulation part 300. Accordingly, the openings 390 may be formed by removing portions of the encapsulation part 300 to have a predetermined depth R.

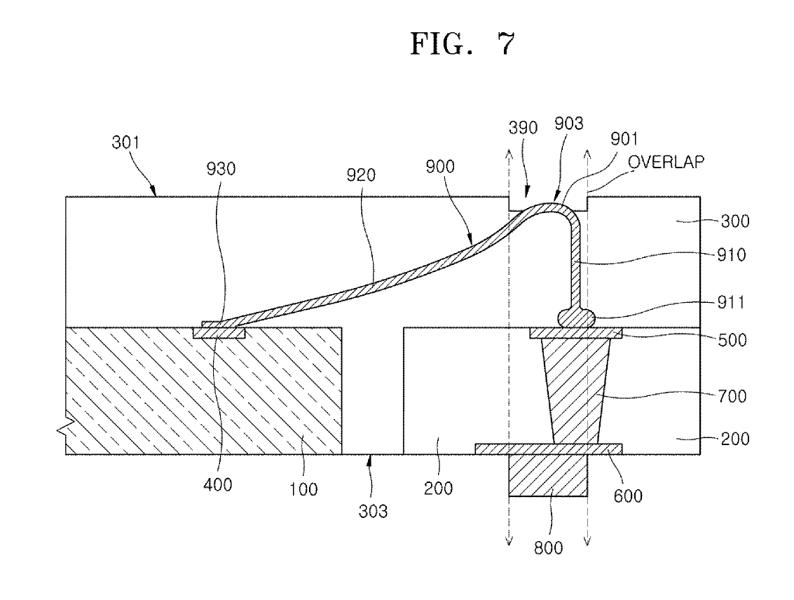

As illustrated in FIG. 7, the opening 390 of the encapsulation part 300 may vertically overlap with the first extension portion 910 of the bonding wire 900. The semiconductor package 10 may include connection members 800 attached to the second external contact portions 600, and each of the connection members 800 may vertically overlap with at least a portion of any one of the openings 390. That is, each of the connection members 800 may be vertically aligned with at least a portion of any one of the openings 390. The connection members 800 may be solder bumps, which are used to connect semiconductor packages to each other or connect a semiconductor package to another package substrate.

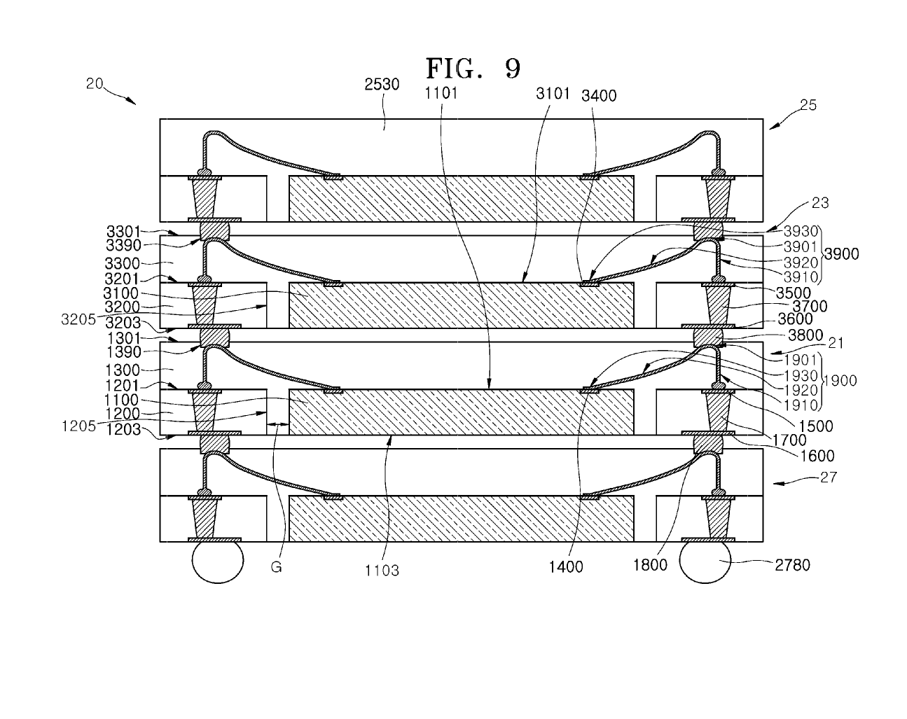

FIG. 9 is a cross-sectional view illustrating a semiconductor stack package 20 according to another embodiment.

Referring to FIG. 9, the semiconductor stack package 20 may include a first sub-package 21 and a second sub-package 23 stacked on the first sub-package 21. The first sub-package 21 and the second sub-package 23 may have substantially the same configuration as the semiconductor package 10 described with reference to FIGS. 1 to 8. The semiconductor stack package 20 may further include a third sub-package 25 stacked on a top surface of the second sub-package 23 opposite to the first sub-package 21, and a fourth sub-package 27 stacked on a bottom surface of the first sub-package 21 opposite to the second sub-package 23. In some embodiments, a plurality of additional semiconductor packages may be stacked on the top surface of the second sub-package 23 opposite to the first sub-package 21 or on the bottom surface of the first sub-package 21 opposite to the second sub-package 23. In such a case, each of the plurality of additional semiconductor packages may also have substantially the same configuration as the semiconductor package 10 described with reference to FIGS. 1 to 8.

The first sub-package 21 may include a first semiconductor die 1100 having a first surface 1101 at which first inner internal contact portions 1400 are disposed. The first inner internal contact portions 1400 may be disposed in edge portions of the first semiconductor die 1100. The first sub-package 21 may further include a first package substrate 1200 having a first cavity 1205 in which the first semiconductor die 1100 is disposed and having a third surface 1201 at which first outer internal contact portions 1500 are disposed. The first sub-package 21 may further include first bonding wires 1900 that electrically connect the first inner internal contact portions 1400 to the first outer internal contact portions 1500.

The first sub-package 21 may further include a first encapsulation part 1300 covering the first surface 1101 of the first semiconductor die 1100 and the third surface 1201 of the first package substrate 1200. The first sub-package has a fifth surface 1301 that includes first openings 1390 that expose first upper external contact portions 1901 of the first bonding wires 1900. Each of the first bonding wires 1900 may have a filament structure including a first substrate connection portion 1911, a first extension portion 1910, an upper bend 1903, a second extension portion 1920 and a first die connection portion 1930 in series. The first encapsulation part 1300 may fill a gap region G between the first semiconductor die 1100 and the first package substrate 1200 and may have a lower surface co-planar with a second surface 1103 of the first semiconductor die 1100.

The first package substrate 1200 of the first sub-package 21 may include a fourth surface 1203 opposite to the third surface 1201 at which the first outer internal contact portions 1500 are disposed, first lower external contact portions 1600 disposed at the fourth surface 1203, and first internal connectors 1700 electrically connecting the first lower external contact portions 1600 to the first outer internal contact portions 1500. The first package substrate 1200 may further include first connection members 1800 attached to the first lower external contact portions 1600 to protrude from surfaces of the first lower external contact portions 1600.

The second sub-package 23 may include a second semiconductor die 3100 having a first surface 3101 at which second inner internal contact portions 3400 are disposed. The second inner internal contact portions 3400 may be disposed in edge portions of the second semiconductor die 3100. The second sub-package 23 may further include a second package substrate 3200 having a second cavity 3205 in which the second semiconductor die 3100 is disposed, the second package substrate 3200 having a third surface 3201 at which second outer internal contact portions 3500 are disposed. The second sub-package 23 may further include second bonding wires 3900 that electrically connect the second inner internal contact portions 3400 to the second outer internal contact portions 3500.

The second sub-package 23 may further include a second encapsulation part 3300 covering the first surface 3101 of the second semiconductor die 3100 and the third surface 3201 of the second package substrate 3200, the second encapsulation part 3300 having a fifth surface 3301 that includes second openings 3390 exposing second upper external contact portions 3901 of the second bonding wires 3900. Each of the second bonding wires 3900 may have a filament structure including a second substrate connection portion, a third extension portion 3910 extending from the second substrate connection portion, an upper bend 3903 exposing the second upper external contact portion 3901, a fourth extension portion 3920 and a second die connection portion 3930 in series. The second encapsulation part 3300 may fill a gap region G between the second semiconductor die 3100 and the second package substrate 3200 and may have a lower surface co-planar with a second surface 3103 of the second semiconductor die 3100 opposite to the second encapsulation part 3300.

The second package substrate 3200 of the second sub-package 23 may include a fourth surface 3203 at which the second outer internal contact portions 3500 are disposed, second lower external contact portions 3600 disposed at the fourth surface 3203, and second internal connectors 3700 electrically connecting the second lower external contact portions 3600 to the second outer internal contact portions 3500. Second connection members 3800 attached to the second lower external contact portions 3600 may protrude from surfaces of the second lower external contact portions 3600. The second connection members 3800 may have substantially the same shape as the first connection members 1800.

The third sub-package 25 stacked on the second sub-package 23 may have substantially the same configuration and shape as the semiconductor package 10 of FIG. 1 except that a third encapsulation part 2530 of the third sub-package 25 may bury entire portions of bonding wires therein.

The fourth sub-package 27 stacked on the bottom surface of the first sub-package 21 may have substantially the same configuration and shape as the semiconductor package 10 of FIG. 1 except that each of third connection members 2780 of the fourth sub-package 27 has a shape which is different from a shape of the first connection members 1800. For example, a size of the third connection members 2780 may be greater than a size of the first connection members 1800. The third connection members 2780 may electrically connect the semiconductor stack package 20 to an external system or another substrate.

A total thickness of the semiconductor stack package 20 may be reduced compared to a conventional stack package. In particular, a conventional stack package includes an adhesive layer that is not present in embodiments of the present disclosure, resulting in reduced thickness. In an embodiment of this disclosure, a thickness of each of the sub-packages does not exceed a sum of thicknesses of a semiconductor die, an encapsulation part, and an external connection member. Each semiconductor die in the semiconductor stack package 20 may be attached or fixed to a package substrate by an encapsulation part without use of an adhesive agent. Thus, an adhesion failure rate between the semiconductor die and the package substrate may be reduced to improve a process yield of the semiconductor package 10 or the semiconductor stack package 20. Moreover, since the semiconductor package 10 or the semiconductor stack package 20 is provided without using the adhesive agent, a thickness of the semiconductor package 10 or the semiconductor stack package 20 may be minimized.

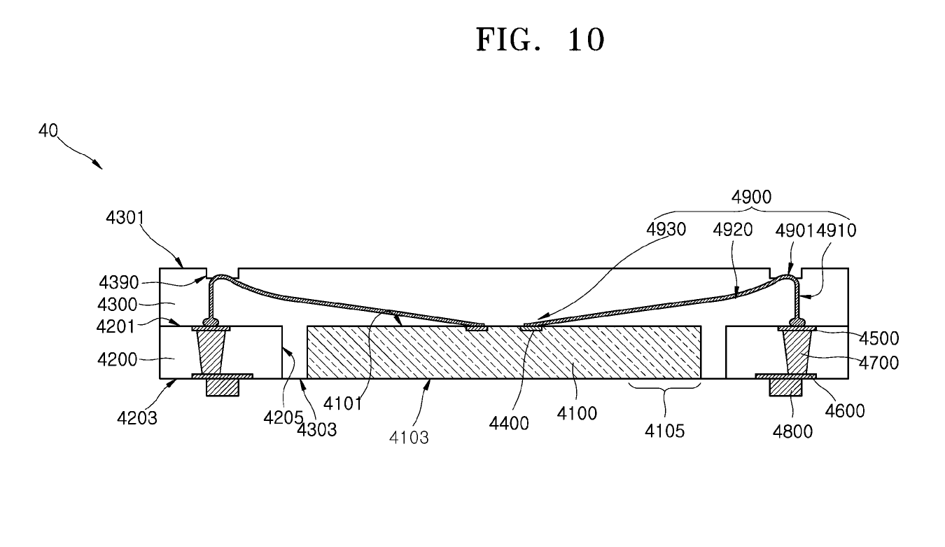

FIG. 10 is a cross-sectional view illustrating a semiconductor package 40 according to another embodiment.

Referring to FIG. 10, the semiconductor package 40 may include a semiconductor die 4100 having a first surface 4101 at which first internal contact portions 4400 are disposed. The first internal contact portions 4400 may be disposed in central portions of the semiconductor die 4100. The semiconductor package 40 may further include a package substrate 4200 having a cavity 4205 in which the semiconductor die 4100 is disposed, the package substrate 4200 having a third surface 4201 at which second internal contact portions 4500 are disposed. The semiconductor package 40 may further include bonding wires 4900 that electrically connect the first internal contact portions 4400 to the second internal contact portions 4500.

The semiconductor package 40 may further include an encapsulation part 4300 covering the first surface 4101 of the semiconductor die 4100 and the third surface 4201 of the package substrate 4200, the encapsulation part 4300 having a fifth surface 4301 that includes openings 4390 exposing first external contact portions 4901 of the bonding wires 4900. Each of the bonding wires 4900 may have a filament structure including a substrate connection portion, a first extension portion 4910, the first external contact portion 4901, a second extension portion 4920 and a die connection portion 4930. Because the first internal contact portions 4400 are disposed in central portions of the semiconductor die 4100, a length of each bonding wire 4900 may be greater than a length of each bonding wire 900 of the semiconductor package 10 shown in FIG. 1. The encapsulation part 4300 may fill a gap region between the semiconductor die 4100 and the package substrate 4200 and may have a lower surface co-planar with a second surface 4103 of the semiconductor die 4100 opposite to the encapsulation part 4300.

The package substrate 4200 of the semiconductor package 40 may include a fourth surface 4203 at which the second internal contact portions 4500 are disposed, second external contact portions 4600 disposed at the fourth surface 4203, and internal connectors 4700 electrically connecting the second external contact portions 4600 to the second internal contact portions 4500. The package substrate 4200 may further include connection members 4800 attached to the second external contact portions 4600, the connection members 4800 protruding from surfaces of the second external contact portions 4600.

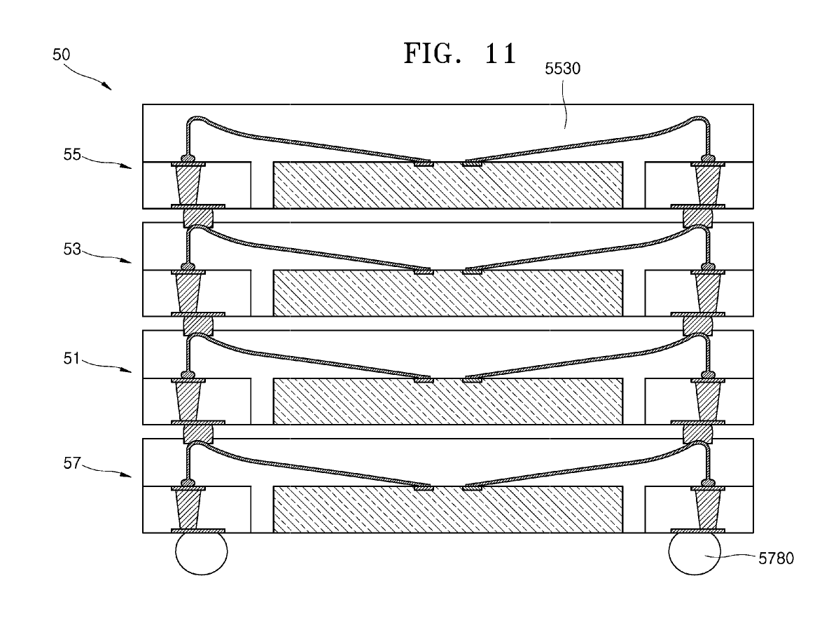

FIG. 11 is a cross-sectional view illustrating a semiconductor stack package 50 according to yet another embodiment.

Referring to FIG. 11, the semiconductor stack package 50 may include a first sub-package 51 and a second sub-package 53 stacked on the first sub-package 51. The first sub-package 51 or the second sub-package 53 may have substantially the same configuration as the semiconductor package 40 described with reference to FIG. 10. The semiconductor stack package 50 may further include a third sub-package 55 stacked on a top surface of the second sub-package 53 opposite to the first sub-package 51 and a fourth sub-package 57 stacked on a bottom surface of the first sub-package 51 opposite to the second sub-package 53. In some embodiments, a plurality of additional semiconductor packages may be stacked above the top surface of the second sub-package 53 opposite to the first sub-package 51 or stacked below the bottom surface of the first sub-package 51 opposite to the second sub-package 53. In such a case, each of the plurality of additional semiconductor packages may also have substantially the same configuration as the semiconductor package 40 described with reference to FIG. 10.

The third sub-package 55 stacked on the second sub-package 53 may have substantially the same configuration and shape as the semiconductor package 40 of FIG. 10 except that a third encapsulation part 5530 of the third sub-package 55 may entirely bury portions of bonding wires therein. The fourth sub-package 57 stacked on the bottom surface of the first sub-package 51 may have substantially the same configuration and shape as the semiconductor package 40 of FIG. 10, except that each third connection member 5780 of the fourth sub-package 57 has a shape that is different from a shape of the connection members (4800 of FIG. 10) of the first, second and third sub-packages 51, 53 and 55. For example, a size of the third connection members 5780 may be greater than a size of the connection members 4800. The third connection members 5780 may electrically connect the semiconductor stack package 50 to an external system or another substrate.

A total thickness of the semiconductor stack package 50 may be reduced compared to a conventional stack package even though a plurality of sub-packages 51, 53, 55 and 57 are stacked in the semiconductor stack package 50. This is because the plurality of sub-packages 51, 53, 55 and 57 are stacked without use of any adhesive agent therebetween. Accordingly, manufacturing costs of the semiconductor stack package 50 may be reduced, and a possibility of adhesion failure due to an adhesive agent may be excluded to improve a process yield of the semiconductor stack package 50. Moreover, since the semiconductor stack package 50 is provided without using the adhesive agent, a thickness of the semiconductor stack package 50 may be minimized.

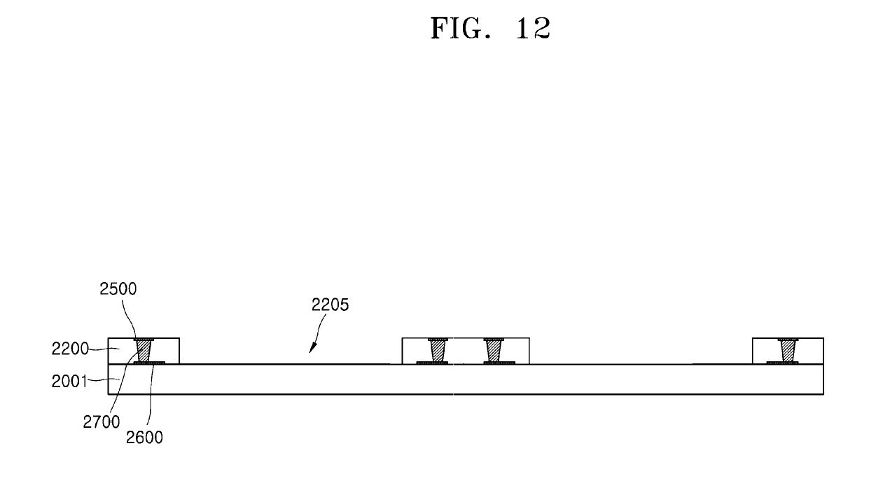

FIGS. 12 to 17 are cross-sectional views illustrating a method of fabricating a semiconductor package according to an embodiment.

Referring to FIG. 12, a package substrate portion 2200 including a plurality of cavities 2205 may be mounted on a carrier 2001. The carrier 2001 may be a substrate, film, or tape. The carrier 2001 may be laminated on a surface of the package substrate portion 2200. The package substrate portion 2200 may include a plurality of package substrates (200 of FIG. 1) that are two-dimensionally arrayed. Thus, the package substrate portion 2200 may include second internal contact portions 2500 disposed at a first surface thereof, second external contact portions 2600 disposed on a second surface, and internal connectors 2700 corresponding to through vias that penetrate a body portion of the package substrate portion 2200 to connect the second internal contact portions 2500 to the second external contact portions 2600.

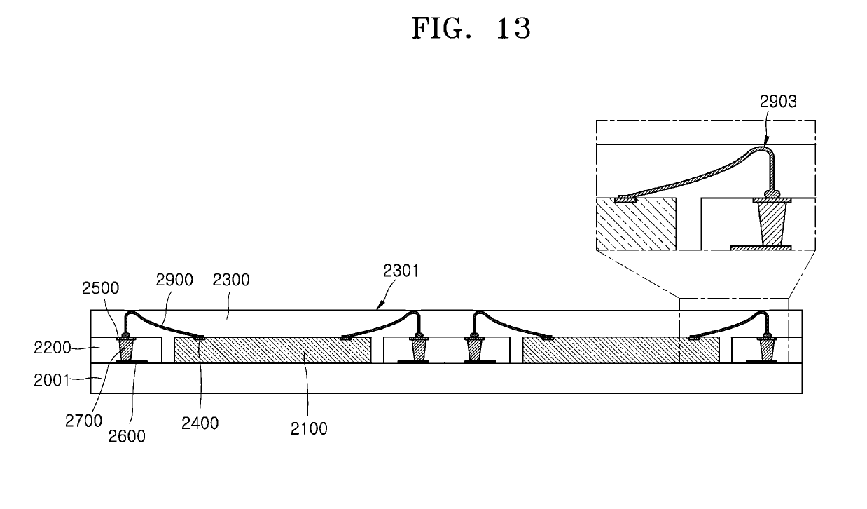

Referring to FIG. 13, semiconductor dies 2100 may be placed in the cavities 2205 of the package substrate portion 2200. Each of the semiconductor dies 2100 may include first internal contact portions 2400 disposed at a surface thereof. The semiconductor dies 2100 may be attached to portions of the carrier 2001, which are exposed by the cavities 2205.

Bonding wires 2900 may be formed using a wire bonding technique to electrically connect the first internal contact portions 2400 of the semiconductor dies 2100 to the second internal contact portions 2500 of the package substrate portion 2200.

An encapsulation part 2300 may cover the package substrate portion 2200 and the semiconductor dies 2100 and to bury the bonding wires 2900 therein. The encapsulation part 2300 may be formed of, for example, an Epoxy Molding Compound (EMC) material. In such a case, the encapsulation part 2300 may be molded so that upper bends 2903 of the bonding wires 2900 are close to a top surface 2301 of the encapsulation part 2300. Alternatively, the encapsulation part 2300 may be molded so that the upper bends 2903 of the bonding wires 2900 are exposed.

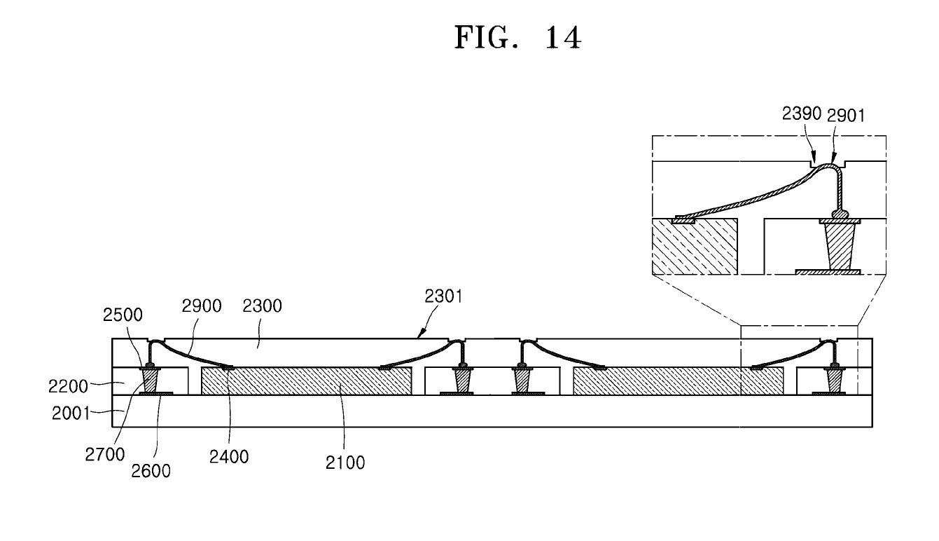

Referring to FIG. 14, portions of the encapsulation part 2300 may be removed to form openings 2390, where a first external contact portion 2901 of one of the bonding wires 2900 is exposed. The openings 2390 may be formed using a laser beam.

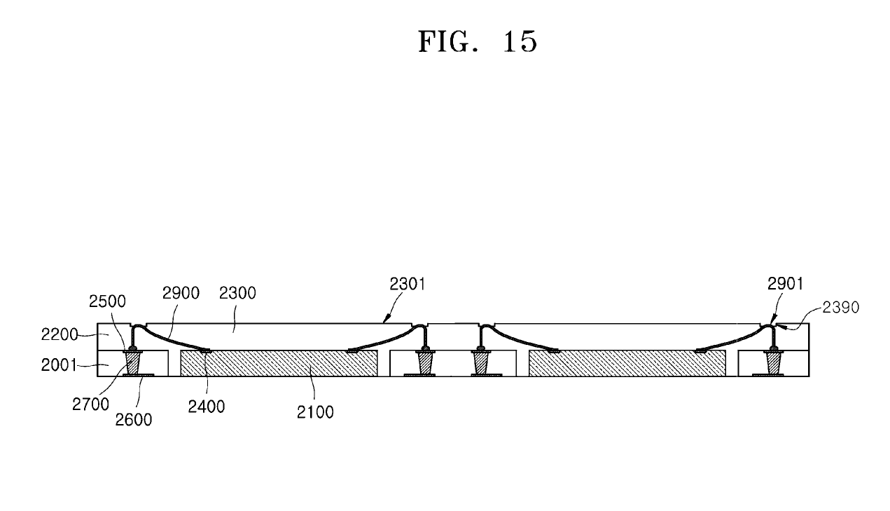

Referring to FIG. 15, the carrier (2001 of FIG. 14) may be removed from the package substrate portion 2200 and the semiconductor dies 2100. Accordingly, the second external contact portions 2600 may be exposed.

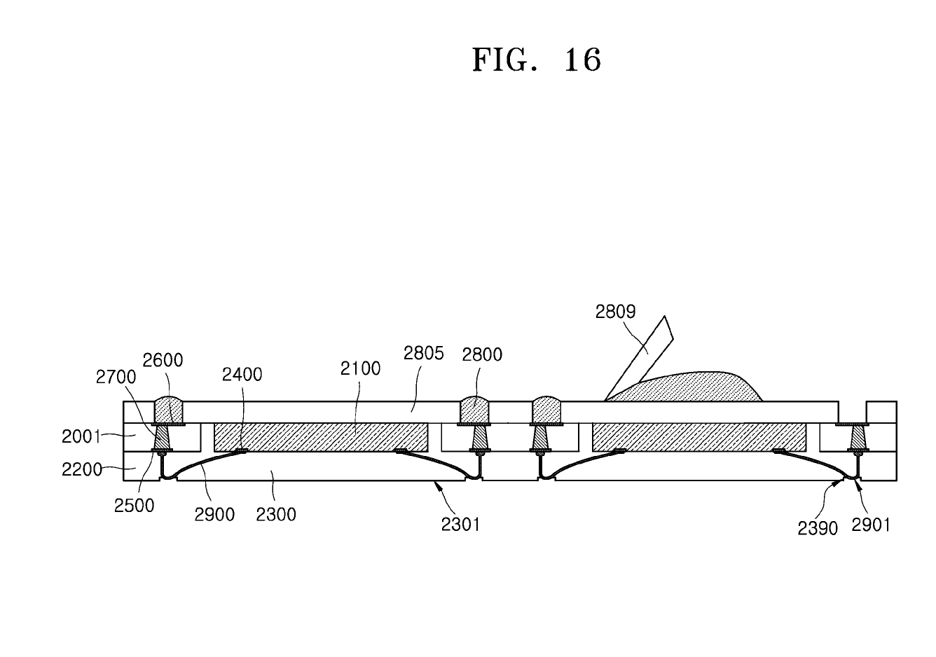

Referring to FIG. 16, a mask 2805 may be formed on exposed surfaces of the package substrate portion 2200 and exposed surfaces of the semiconductor dies 2100. The mask 2805 may have holes that selectively expose the second external contact portions 2600. Connection members 2800 may be formed in the holes of the mask 2805. The mask 2805 may be a stencil mask. In such a case, the connection members 2800 may be formed by coating a conductive material such as a solder paste material on the stencil mask and filling the holes of the stencil mask with the conductive material using a blade 2809. That is, the connection members 2800 may be formed using a printing technique with a stencil mask. The connection members 2800 may have micro bump shapes.

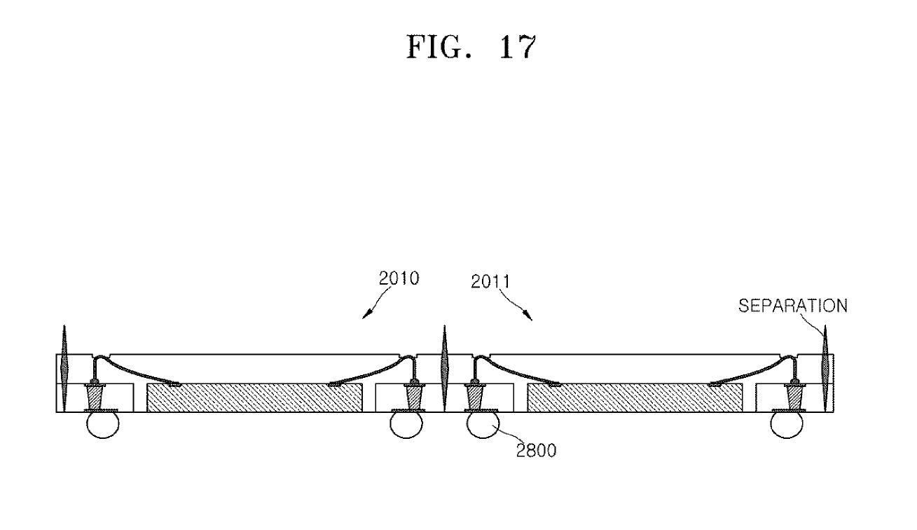

Referring to FIG. 17, after removing the mask 2805, the encapsulation part 2300 and the package substrate portion 2200 may be cut to separate package 2010 from package 2011. For example, packages 2010 and 2011 may be separated from each other using a sawing technique. Packages 2010 and 2011 may be sequentially stacked to form the semiconductor stack package described with reference to FIG. 9 or 11. Specifically, the package 2011 may be stacked on the package 2010 so that the connection members 2800 of the package 2011 are connected to the first external contact portions 2901 of the package 2010. If additional packages are stacked above the package 2011 or under the package 2010 using this manner, the semiconductor stack package shown in FIG. 9 or 11 may be fabricated.

FIG. 18 is a block diagram illustrating an electronic system employing a memory card 7800 including at least one package according to some embodiments. The memory card 7800 includes a memory 7810 such as a nonvolatile memory device, and a memory controller 7820. The memory 7810 and the memory controller 7820 may store data or read stored data. The memory 7810 and/or the memory controller 7820 may include one or more semiconductor package according to an embodiment.

The memory 7810 may include a nonvolatile memory device including a semiconductor package according to embodiments of the present disclosure. The memory controller 7820 may control the memory 7810 such that stored data is read out or data is stored in response to a read/write request from a host 7830.

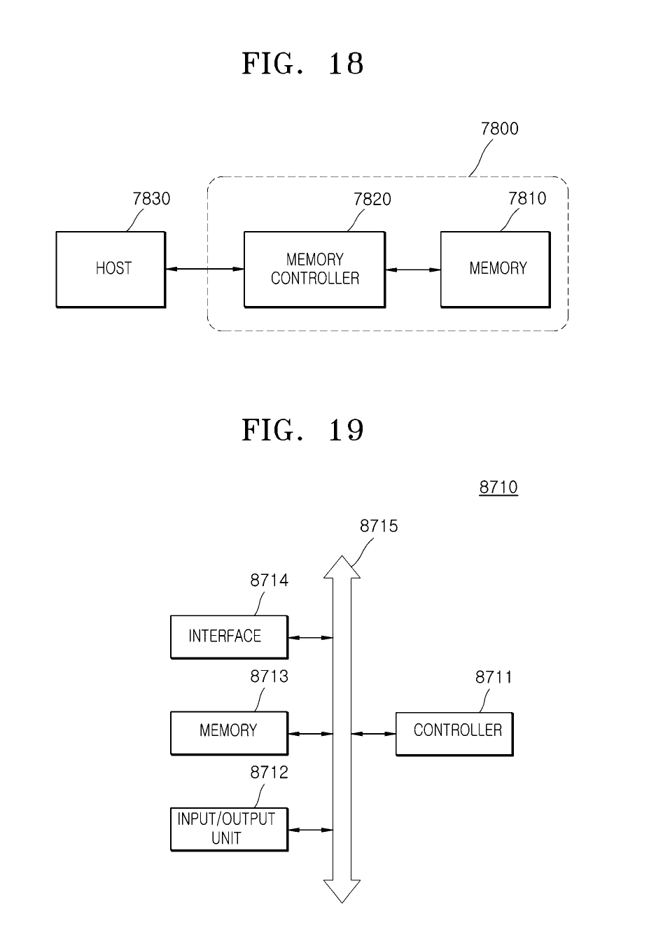

FIG. 19 is a block diagram illustrating an electronic system 8710 including at least one package according to an embodiment. The electronic system 8710 may include a controller 8711, an input/output device 8712, and a memory 8713. The controller 8711, the input/output device 8712 and the memory 8713 may be coupled with one another through a bus 8715 providing a path through which data is transmitted.

In an embodiment, the controller 8711 may include one or more microprocessor, digital signal processor, microcontroller, and/or logic device capable of performing the same functions as these components. The controller 8711 or the memory 8713 may include one or more of the semiconductor packages according to embodiments of the present disclosure. The input/output device 8712 may include at least one selected among a keypad, a keyboard, a display device, a touchscreen and so forth. The memory 8713 is a device for storing data. The memory 8713 may store data and/or commands executed by the controller 8711, etc.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna, a wired transceiver, or a wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

If the electronic system 8710 is an equipment capable of performing wireless communication, the electronic system 8710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution), and Wibro (wireless broadband Internet).

The embodiments of the present disclosure have been disclosed for illustrative purposes. Those skilled in the art will appreciate that various modifications, additions and substitutions are possible, without departing from the scope and spirit of the present disclosure and the accompanying claims.

1. A semiconductor package comprising:
a package substrate having a cavity and a second internal contact portion, wherein the cavity penetrates the package substrate;
a semiconductor die disposed in the cavity of the package substrate, the semiconductor die having a first internal contact portion, wherein the semiconductor die has a first surface and a second surface opposite to the first surface, wherein the first surface is exposed by the package substrate, and wherein the second surface is fully exposed by the package substrate;
a bonding wire connecting the first internal contact portion to the second internal contact portion; and
an encapsulation part covering the first surface of the semiconductor die and a third surface of the package substrate and having an opening that exposes a first external contact portion of the bonding wire.

2. The semiconductor package of claim 1, wherein the bonding wire includes:
a first extension portion extending from the second internal contact portion;
an upper bend extending from the first extension portion and bending toward the first internal contact portion, an exposed part of the upper bend being the first external contact portion; and
a second extension portion extending from the first external contact portion toward the first internal contact portion.

3. The semiconductor package of claim 2, wherein the opening is located over the third surface of the package substrate.

4. (canceled)

5. The semiconductor package of claim 1, wherein the package substrate has a rectangular frame shape and the cavity penetrates a central portion of the package substrate.

6. The semiconductor package of claim 1,
wherein the first internal contact portion is disposed on the first surface, and
wherein the encapsulation part fills a gap region between the semiconductor die and the package substrate, and exposes the second surface of the semiconductor die.

7. The semiconductor package of claim 1, wherein the package substrate includes:
a second external contact portion disposed at a fourth surface opposite to the third surface; and
an internal connector connecting the second internal contact portion to the second external contact portion,
wherein the second internal contact portion is disposed on the third surface.

8. The semiconductor package of claim 7,
wherein the internal connector is a through via that penetrates the package substrate; and
wherein a first end of the through via is connected to the second internal contact portion and a second end of the through via is connected to the second external contact portion.

9. The semiconductor package of claim 8, further comprising an external connection member that is aligned with the opening and protrudes from the second external contact portion.

10. The semiconductor package of claim 1, wherein the first internal contact portion is disposed on an edge portion of the semiconductor die.

11. The semiconductor package of claim 1, wherein the first internal contact portion is disposed in a central portion of the semiconductor die.

12. A semiconductor package comprising:
a first sub-package; and
a second sub-package stacked on the first sub-package,
wherein the first sub-package comprises:
a first package substrate having a first cavity and a first outer internal contact portion, wherein the first cavity penetrates the first package substrate;
a first semiconductor die disposed in the first cavity and having a first inner internal contact portion, wherein the first semiconductor die has a first surface and a second surface opposite to the first surface, wherein the first surface is exposed by the first package substrate, and wherein the second surface is fully exposed by the first package substrate;
a first bonding wire connecting the first inner internal contact portion to the first outer internal contact portion; and
a first encapsulation part covering the first surface of the first semiconductor die and a third surface of the first package substrate, and having a first opening that exposes a first upper external contact portion of the first bonding wire, and
wherein the second sub-package includes a second connection member connected to the first upper external contact portion of the first sub-package.

13. The semiconductor package of claim 12, wherein the second sub-package includes:
a second package substrate having a second cavity and a second outer internal contact portion;
a second semiconductor die disposed in the second cavity and having a second inner internal contact portion;
a second bonding wire connecting the second inner internal contact portion to the second outer internal contact portion; and
a second encapsulation part covering surfaces of the second semiconductor die and the second package substrate.

14. The semiconductor package of claim 13, wherein the second cavity penetrates the second package substrate.

15. The semiconductor package of claim 13,
wherein the second semiconductor die has a first surface at which the second inner internal contact portion is disposed and a second surface opposite to the first surface, and
wherein the second encapsulation part fills a gap region between the second semiconductor die and the second package substrate and exposes the second surface of the second semiconductor die.

16. The semiconductor package of claim 13, wherein
the second package substrate includes:
a third surface at which the second outer internal contact portion is disposed;
a second lower external contact portion disposed at a fourth surface opposite to the third surface; and
a first internal connector connecting the second lower external contact portion to the second outer internal contact portion.

17. The semiconductor package of claim 16,
wherein the first internal connector is a through via that substantially penetrates the second package substrate; and
wherein a first end of the through via is connected to the second lower external contact portion and a second end of the through via is connected to the second outer internal contact portion.

18. The semiconductor package of claim 17, wherein the second connection member of the second sub-package overlaps with the second opening and is connected to the second lower external contact portion.

19. The semiconductor package of claim 18, wherein the first package substrate includes:
a third surface at which the first outer internal contact portion is disposed;
a first lower external contact portion disposed at a fourth surface of the first package substrate opposite to the third surface;
a second internal connector connecting the first lower external contact portion to the first outer internal contact portion; and
a first connection member attached to the first lower external contact portion and protruding from the first lower external contact portion,
wherein the first connection member has substantially the same shape as the second connection member.

20. An electronic system including a package, the package comprising:
a package substrate having a cavity and a second internal contact portion, wherein the cavity penetrates the package substrate;
a semiconductor die disposed in the cavity of the package substrate and having a first internal contact portion, wherein the semiconductor die has a first surface and a second surface opposite to the first surface, wherein the first surface is exposed by the package substrate, and wherein the second surface is fully exposed by the package substrate;
a bonding wire connecting the first internal contact portion to the second internal contact portion; and
an encapsulation part covering the first surface of the semiconductor die and a third surface of the package substrate, and providing an opening that exposes a portion of the bonding wire,
wherein the exposed portion of the bonding wire acts as a first external contact portion.
